(19) United States
(12) Patent Application Publication
(10) Pub. No.: US 2025/0132189 A1
(43) Pub. Date: Apr. 24, 2025

(54) LIFT PINS INCLUDING OPENING, AND RELATED COMPONENTS AND CHAMBER KITS, FOR PROCESSING CHAMBERS

(71) Applicant: Applied Materials, Inc., Santa Clara, CA (US)

(72) Inventors: Masato ISHII, Sunnyvale, CA (US); Ryan Sungbin HU, Santa Clara, CA (US); Kuan Chien SHEN, Sunnyvale, CA (US)

(21) Appl. No.: 18/382,421

(22) Filed: Oct. 20, 2023

(51) Int. Cl. H01L 21/687; C23C 16/458

(52) U.S. Cl. CPC H01L 21/68742; C23C 16/4585

(57) ABSTRACT

The present disclosure relates to lift pins that include an opening, and related components and chamber kits, for disposition in processing chambers for semiconductor manufacturing. In one or more embodiments, a processing chamber applicable for use in semiconductor manufacturing includes a chamber body and a window. The processing chamber includes one or more heat sources, a substrate support, and a plurality of lift pins disposed in a processing volume. The plurality of lift pins respectively include a shaft section having a first outer dimension, a head section having a second outer dimension, and an opening formed in the shaft section. The opening has a dimension that is a first ratio that is at least 0.3 of the first outer dimension of the shaft section. The dimension of the opening is a second ratio that is at least 0.2 of the second outer dimension of the head section.

### BACKGROUND

### Field

The present disclosure relates to lift pins that include an opening, and related components and chamber kits, for disposition in processing chambers for semiconductor manufacturing.

### Description of the Related Art

Semiconductor substrates are processed for a wide variety of applications, including the fabrication of integrated devices and microdevices. During processing, various parameters can affect the uniformity of material deposited on the substrate. For example, the temperature of the substrate and/or temperature(s) of processing chamber component(s) can affect deposition uniformity. As another example, temperature differences (such as temperature gradients) in processing chambers can affect film deposition uniformity and site-front-least-squares-range, which can hinder device performance and reduce throughput. Moreover, operations can degrade components (causing lower lifespans) and can cause thermal shock.

Therefore, a need exists for improved chamber components that facilitate temperature uniformities.

### SUMMARY

The present disclosure relates to lift pins that include an opening, and related components and chamber kits, for disposition in processing chambers for semiconductor manufacturing.

In one or more embodiments, a processing chamber applicable for use in semiconductor manufacturing includes a chamber body and a window, the chamber body and the window at least partially defining a processing volume. The processing chamber includes one or more heat sources configured to heat the processing volume, a substrate support disposed in the processing volume, and a plurality of lift pins disposed in the processing volume. The plurality of lift pins respectively include a shaft section having a first outer dimension, a head section having a second outer dimension, and an opening formed in the shaft section. The opening has a dimension that is a first ratio that is at least 0.3 of the first outer dimension of the shaft section. The dimension of the opening is a second ratio that is at least 0.2 of the second outer dimension of the head section.

In one or more embodiments, a lift pin applicable for semiconductor manufacturing includes a head section, a shaft section extending relative to the head section, and an opening formed in an end face of the shaft section and extending toward the head section.

In one or more embodiments, a lift pin applicable for semiconductor manufacturing includes a head section including a first material, and a shaft section extending relative to the head section. The shaft section includes a second material that has a different composition than the first material. The lift pin includes an opening formed in the shaft section.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic side cross-sectional view of a processing chamber, according to one or more embodiments.

FIG. 2 is a schematic side cross-sectional view of one of the lift pins shown in FIG. 1, according to one or more embodiments.

FIG. 3 is a schematic side cross-sectional view of a lift pin, according to one or more embodiments.

FIG. 4 is a schematic side cross-sectional view of a lift pin, according to one or more embodiments.

FIG. 5 is a schematic enlarged side cross-sectional view of a lift pin, according to one or more embodiments.

FIG. 6 is a schematic side cross-sectional view of a lift pin, according to one or more embodiments.

FIG. 7 is a schematic partial top view of the processing chamber shown in FIG. 1 with the lift pin shown in FIG. 2, according to one or more embodiments.

FIG. 8 is a graph illustrating film thickness (in nm) versus substrate radius (in mm) for a region of a substrate aligned above a lift pin, according to one or more embodiments.

FIG. 9 is a schematic block diagram view of a method of substrate processing for semiconductor manufacturing, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to lift pins that include an opening, and related components and chamber kits, for disposition in processing chambers for semiconductor manufacturing.

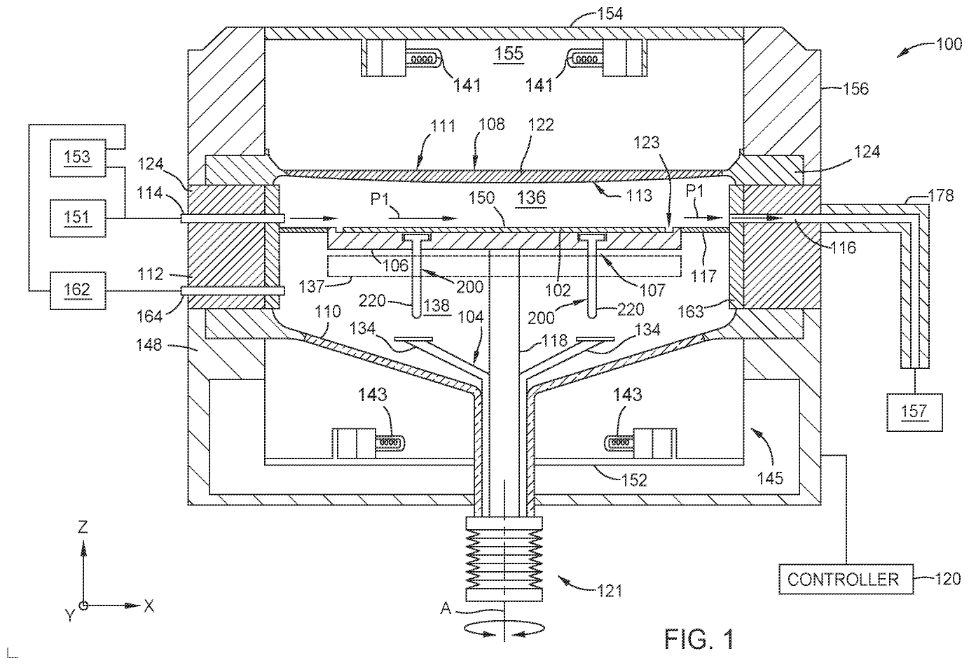

FIG. 1 is a schematic side cross-sectional view of a processing chamber 100, according to one or more embodiments. The processing chamber 100 is a deposition chamber. In one or more embodiments, which can be combined with other embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body. Disposed within the chamber body is a substrate support 106, an upper window 108 (such as an upper dome), a lower window 110 (such as a lower dome), a plurality of upper heat sources 141, and a plurality of lower heat sources 143. As shown, a controller 120 is in communication with the processing chamber 100 and is used to control processes and methods, such as the operations of methods described herein. The controller 120 and the processing chamber 100 can be part of a substrate processing system.

In the implementation shown in FIG. 1, the heat sources 141, 143 are lamps. Other heat sources are contemplated for the heat sources described herein, such as resistive heaters, light emitting diodes (LEDs), and/or lasers.

The substrate support 106 is disposed between the upper window 108 and the lower window 110. The substrate support 106 includes a support face 123 that supports the substrate 102. The plurality of upper heat sources 141 are disposed between the upper window 108 and a lid 154. The plurality of upper heat sources 141 form a portion of the upper heating module 155. The lid 154 may include a plurality of sensors (such as pyrometers) disposed therein or thereon for measuring the temperature within the processing chamber 100. The plurality of lower heat sources 143 are disposed between the lower window 110 and a chamber floor 152. The plurality of lower heat sources 143 form a portion of a lower heating module 145. The upper window 108 is an upper dome and is formed at least partially of an energy transmissive material, such as quartz. The lower window 110 is a lower dome and is formed at least partially of an energy transmissive material, such as quartz.

A process volume 136 and a purge volume 138 are positioned between the upper window 108 and the lower window 110. The process volume 136 and the purge volume 138 are part of an internal volume defined at least partially by the upper window 108, the lower window 110, and the one or more liners 163. The upper window 108 at least partially defines the process volume 136.

The window 108 includes a first face 111 that is concave or flat (in the implementation shown in FIG. 1, the first face 111 is flat). The upper window 108 includes a second face 113 that is convex. The second face 113 faces the substrate support 106. The present disclosure contemplates other shapes for the upper window 108. The upper window 108 includes an inner section 122 and an outer section 124. The first face 111 and the second face 113 are at least part of the inner section 122. In one or more embodiments, the inner section 122 is transparent and the outer section 124 is opaque. The outer section 124 is received at least partially in one or more sidewalls (such as in the flow module 112) of the processing chamber 100.

The internal volume has the substrate support 106 disposed therein. The substrate support 106 includes a top surface on which the substrate 102 is disposed. The substrate support 106 is attached to a shaft 118. The shaft 118 is connected to a motion assembly 121. The motion assembly 121 includes one or more actuators and/or adjustment devices that provide movement and/or adjustment for the shaft 118 and/or the substrate support 106 within the processing volume 136. In one or more embodiments, the substrate support 106 includes a susceptor. Other substrate supports (including, for example, a substrate carrier and/or one or more ring segment(s) that support one or more outer regions of the substrate 102) are contemplated by the present disclosure.

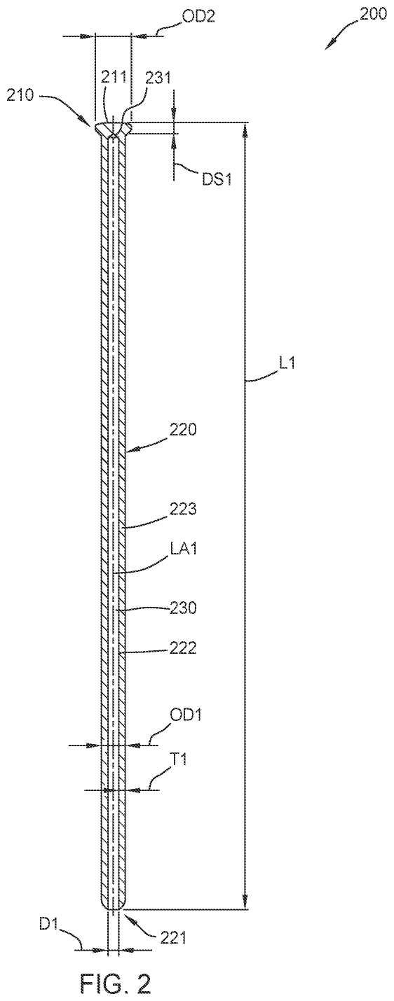

The substrate support 106 may include openings 107 (e.g., lift pin holes) formed therein. The openings 107 are each sized to accommodate a lift pin 200 for lifting of the substrate 102 from the substrate support 106 either before or after a deposition process is performed. The lift pins 200 are disposed in the openings 107 in FIG. 1. The lift pins 200 may rest on lift pin stops 134 when the substrate support 106 is lowered from a process position to a transfer position. The lift pin stops 134 can be coupled to a second shaft 104. The lift pins 200 (described below and shown in FIG. 2) are partially shown in FIG. 1 and are shown without hatching in FIG. 1 for visual clarity purposes.

The flow module 112 includes a plurality of gas inlets 114, a plurality of purge gas inlets 164, and one or more gas exhaust outlets 116. The plurality of gas inlets 114 and the plurality of purge gas inlets 164 are disposed on the opposite side of the flow module 112 from the one or more gas exhaust outlets 116. One or more flow guides 117 are disposed below the plurality of gas inlets 114 and the one or more gas exhaust outlets 116. The one or more flow guides can include, for example, one or more pre-heat rings. The one or more flow guides 117 are disposed above the purge gas inlets 164. One or more liners 163 are disposed on an inner surface of the flow module 112 and protects the flow module 112 from reactive gases used during deposition operations and/or cleaning operations. The gas inlet(s) 114 and the purge gas inlet(s) 164 are each positioned to flow a gas parallel to the top surface 150 of a substrate 102 disposed within the process volume 136. The gas inlet(s) 114 are fluidly connected to one or more process gas sources 151 and one or more cleaning gas sources 153. The purge gas inlet(s) 164 are fluidly connected to one or more purge gas sources 162 and/or the one or more cleaning gas sources 153. The one or more gas exhaust outlets 116 are fluidly connected to an exhaust pump 157. One or more process gases P1 supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). One or more purge gases supplied using the one or more purge gas sources 162 can include one or more inert gases (such as one or more of argon (Ar), helium (He), hydrogen (H₂), and/or nitrogen (N₂)). One or more cleaning gases supplied using the one or more cleaning gas sources 153 can include one or more of hydrogen (H) and/or chlorine (CI). In one or more embodiments, the one or more process gases P1 include silicon phosphide (SiP) and/or phospine (PH₃), and the one or more cleaning gases include hydrochloric acid (HCl).

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. The exhaust system 178 is disposed on an opposite side of the processing chamber 100 relative to the flow module 112.

The controller 120 includes a central processing unit (CPU), a memory containing instructions, and support circuits for the CPU. The controller 120 controls various items directly, or via other computers and/or controllers. In one or more embodiments, the controller 120 is communicatively coupled to dedicated controllers, and the controller 120 functions as a central controller.

The controller 120 is of any form of a general-purpose computer processor that is used in an industrial setting for controlling various substrate processing chambers and equipment, and sub-processors thereon or therein. The memory, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits of the controller 120 are coupled to the CPU for supporting the CPU (a processor). The support circuits include cache, power supplies, clock circuits, input/output circuitry and subsystems, and the like. Operational parameters (e.g., a position of the lift pins 200, a pressure for process gas, a flow rate for process gas, and/or a rotational position of a process kit) and operations are stored in the memory as a software routine that is executed or invoked to turn the controller 120 into a specific purpose controller to control the operations of the various chambers/modules described herein. The controller 120 is configured to conduct any of the operations described herein. The instructions stored on the memory, when executed, cause one or more operations of the methods described herein to be conducted.

The various operations described herein can be conducted automatically using the controller 120, or can be conducted automatically or manually with certain operations conducted by a user.

The controller 120 is configured to control the rotational position, the heating, and gas flow through the processing chamber 100 by providing an output to controls for the heat sources 141, 143, the gas flow, and the motion assembly 121. The controls include controls for the upper heat sources 141, the lower heat sources 143, the process gas source 151, the purge gas source 162, the motion assembly 121, and the exhaust pump 157.

The controller 120 is configured to adjust the output to the controls based off of sensor readings, a system model, and stored readings and calculations. The controller 120 includes embedded software and a compensation algorithm(s) to calibrate measurements. The controller 120 can include one or more machine learning algorithms and/or artificial intelligence algorithms that estimate optimized parameters for the deposition operations, the purge operations, and/or the cleaning operations. The one or more machine learning algorithms and/or artificial intelligence algorithms can use, for example, a regression model (such as a linear regression model) or a clustering technique to estimate optimized parameters. The algorithm can be unsupervised or supervised.

Substrates (such as the substrate 102) are transferred into and out of the internal volume of the processing chamber 100 through a transfer door 137 (such as a slit valve). When the transfer door 137 is open, a transfer apparatus (with a substrate supported thereon) can extend into the internal volume through the transfer door 137 such that the lift pins 200 can lift the substrate from the transfer apparatus and land the substrate on the substrate support 106 for processing. After processing, the lift pins 200 can lift the substrate from the substrate support 106 and land the substrate on a transfer apparatus, and the transfer apparatus can be retracted through the open transfer door 137 to remove the substrate from the processing chamber 100.

FIG. 2 is a schematic side cross-sectional view of one of the lift pins 200 shown in FIG. 1, according to one or more embodiments.

The lift pin 200 includes a head section 210 and a shaft section 220 extending relative to the head section 210. In one or more embodiments the lift pin 200 is at least partially hollow. In the implementation shown in FIG. 2, the lift pin 200 is partially hollow. The lift pin 200 includes an opening 230 formed in an end face 221 of the shaft section 220 and extending toward the head section 210.

The shaft section 220 has a first outer dimension OD1 and the opening 230 has a dimension D1 that is a first ratio of the first outer dimension OD1 of the shaft section 220, and the first ratio is at least 0.3. In one or more embodiments, the first outer dimension OD1 is within a range of 2.5 mm to 4.5 mm, such as within a range of 3.4 mm to 3.5 mm. The dimension D1 at least partially defines an inner surface 222 of the shaft section 220. In one or more embodiments, the first ratio is within a range of 0.35 to 0.45. In one or more embodiments, the first ratio is within a range of 0.43 to 0.44. The head section 210 has a second outer dimension OD2. The dimension D1 of the opening 230 is a second ratio of the second outer dimension OD2 of the head section 210, and the second ratio is at least 0.2. In one or more embodiments, the second ratio is within a range of 0.25 to 0.35. In one or more embodiments, the second ratio is within a range of 0.28 to 0.30. In one or more embodiments, the dimension D1 is within a range of 0.1 mm to 3.5 mm, such as within a range of 1.3 mm to 1.7 mm. In one or more embodiments, the dimensions D1 is within a range of 1.4 mm to 1.6 mm. In one or more embodiments, the second outer dimension OD2 is greater than 2.5 mm, such as greater than 3.0 mm. In one or more embodiments, the second outer dimension OD2 is within a range of 4.0 mm to 6.0 mm, such as within a range of 5.0 mm to 5.3 mm.

In the implementation shown in FIG. 2, the opening 230 includes a recess extending along a longitudinal axis LA1 of the shaft section 220 and defining a recessed inner surface 231 at a distance DS1 from a support surface 211 of the head section 210. The recessed inner surface 231 can be planar, tapered, and/or arcuate. Other shapes are contemplated for the recessed inner surface 231. In the implementation shown in FIG. 2, the recessed inner surface 231 is tapered, and the distance DS1 is between an outermost point along the support surface 211 and an apex of the recessed inner surface 231.

The opening 230 at least partially defines a wall 223 of the shaft section 220. A thickness T1 of the wall 223 is a third ratio of the dimension D1 of the opening 230, and the third ratio is 1.15 or less. In one or more embodiments, the third ratio is within a range of 1.11 to 1.13. In one or more embodiments, the thickness T1 of the wall 223 is within a range of 0.1 mm to 1.7 mm. In one or more embodiments, the thickness T1 is within a range of 0.9 mm to 1.1 mm. The distance DS1 is a fourth ratio of a length L1 of the lift pin 200. The third ratio is 0.05 or less. In one or more embodiments, the fourth ratio is 0.02 or less. In one or more embodiments, the fourth ratio is within a range of 0.01 to 0.15. In one or more embodiments, the distance DS1 is less than 4.0 mm. In one or more embodiments, the distance DS1 is within a range of 0.5 mm to 2.0 mm, such as within a range of 1.45 mm to 1.7 mm. In one or more embodiments, the length L1 is greater than 90 mm, such as within a range of 100 mm to 125 mm.

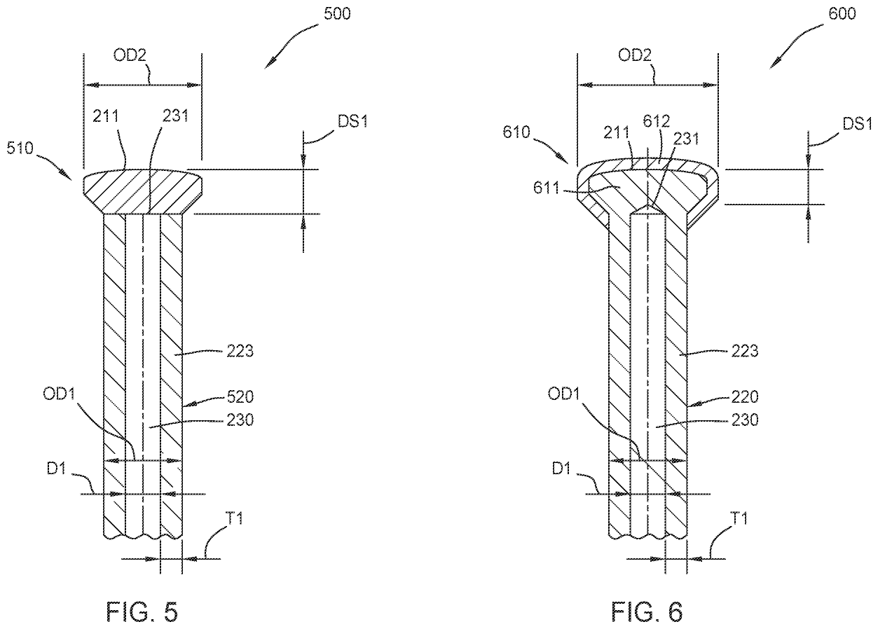

The support surface 211 can be planar, tapered, and/or arcuate. Other shapes are contemplated for the recessed inner surface 231. In the implementation shown in FIG. 2, the support surface 211 is arcuate. The support surface 211 at least partially supports the substrate 102 shown in FIG. 1 when the support surface 211 contacts and lifts the substrate 102. The support surface 211 can contact and lift other components (such as a substrate carrier that carries the substrate 102). In one or more embodiments, the head section 210 and the shaft section 220 each includes glass carbon. The head section 210 and the shaft section 220 can be monolithically formed as a single body, or the head section 210 and the shaft section 220 can be coupled together. Other configurations are contemplated for the head section 210 and the shaft section 220. The present disclosure contemplates that the head section 210 and the shaft section 220 can include materials having different compositions (for example, as described in FIGS. 5 and 6 below).

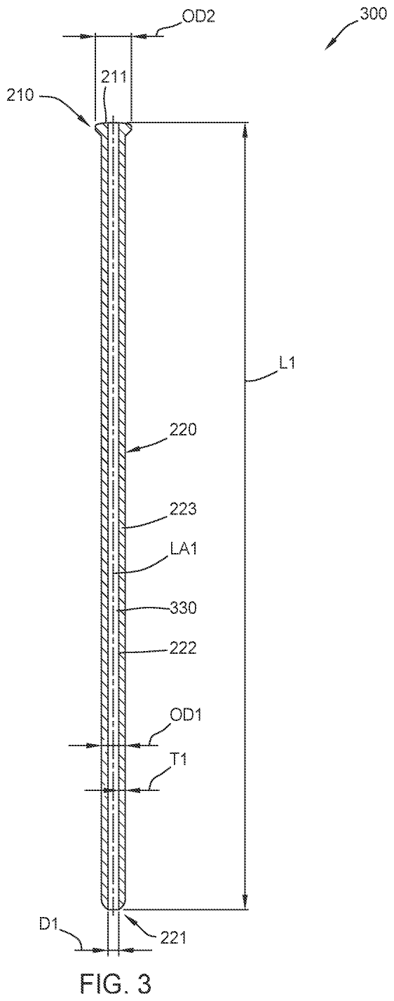

FIG. 3 is a schematic side cross-sectional view of a lift pin 300, according to one or more embodiments. The lift pin 300 can be used in place of one or more (such as one or all) of the lift pins 200 shown in FIG. 1).

The lift pin 300 is similar to the lift pin 200 shown in FIG. 2, and includes one or more aspects, features, components, operations, and/or properties. The lift pin 300 includes an opening 330 extending from the end face 221 of the shaft section 220 and extending to the support surface 211 of the head section 210. The opening 330 is a through-hole. The opening 330 extends through the shaft section 220 and through the head section 210 such that the lift pin 300 is hollow along the length L1.

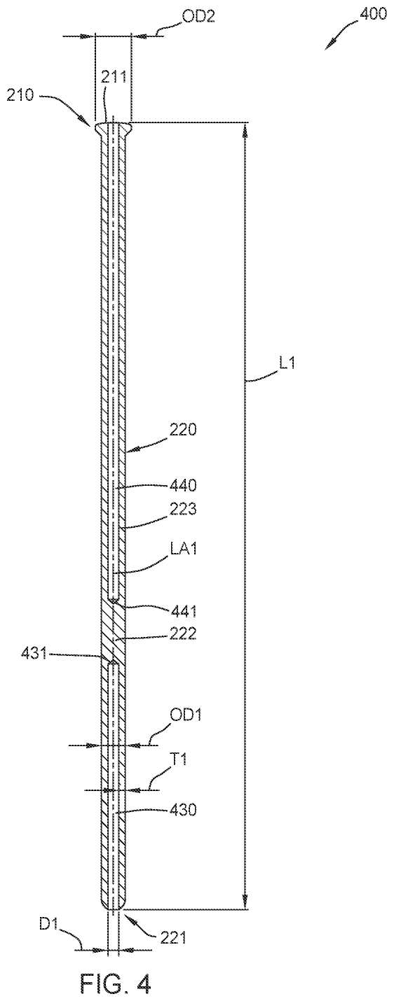

FIG. 4 is a schematic side cross-sectional view of a lift pin 400, according to one or more embodiments. The lift pin 400 can be used in place of one or more (such as one or all) of the lift pins 200 shown in FIG. 1).

The lift pin 400 is similar to the lift pin 200 shown in FIG. 2, and includes one or more aspects, features, components, operations, and/or properties. The lift pin 400 includes a first opening 430 formed in the end face 221 of the shaft section 220 and extending toward the head section 210, and a second opening 440 formed in the support surface 211 of the head section 210 an extending toward the shaft section 220. In one or more embodiments, the first opening 430 includes a first recess defining a first recessed inner surface 431, and the second opening 440 includes a second recess defining a second recessed inner surface 441. A portion 423 of the shaft section 420 is between the first recessed inner surface 431 and the second recessed inner surface 441. The portion 423 of the shaft section 420 fluidly isolates the second opening 440 from the first opening 430.

FIG. 5 is a schematic enlarged side cross-sectional view of a lift pin 500, according to one or more embodiments. The lift pin 500 can be used in place of one or more (such as one or all) of the lift pins 200 shown in FIG. 1).

The lift pin 500 is similar to the lift pin 200 shown in FIG. 2, and includes one or more aspects, features, components, operations, and/or properties. A head section 510 of the lift pin 500 includes a first material, and a shaft section 520 of the lift pin 500 includes second material that has a different composition than the first material. In one or more embodiments, the second material of the shaft section 520 has a lower thermal conductivity than the first material of the head section 510. In one or more embodiments, the second material includes glassy carbon, and the first material includes quartz (such as transparent quartz and/or opaque quartz, such as white quartz, grey quartz, and/or black quartz), silicon carbide (SiC), and/or graphite coated with SiC and/or quartz. In one or more embodiments, the head section 510 includes a first body formed of the first material, the shaft section 520 includes a second body formed of the second material, and the first body and the second body are coupled (e.g., bonded, welded, and/or fused) together. In one or more embodiments, the opening 230 is a through-hole extending through the shaft section 520, and the head section 510 is coupled to the shaft section 520 to at least partially define the recessed inner surface 231.

FIG. 6 is a schematic side cross-sectional view of a lift pin 600, according to one or more embodiments. The lift pin 600 can be used in place of one or more (such as one or all) of the lift pins 200 shown in FIG. 1).

The lift pin 600 is similar to the lift pin 500 shown in FIG. 5, and includes one or more aspects, features, components, operations, and/or properties. A head section 610 of the lift pin 600 includes a first material, and the shaft section 220 of the lift pin 600 includes second material that has a different composition than the first material. The head section 610 is similar to the head section 210 shown in FIG. 2. The second material of the shaft section 220 includes glassy carbon, and the first material of the head section 610 includes glassy carbon as a portion 611 and a coating 612 disposed on the support surface 211 of the head section 610. The coating 612 includes silicon carbide (SiC) or quartz (such as transparent quartz and/or opaque quartz, such as white quartz, grey quartz, and/or black quartz).

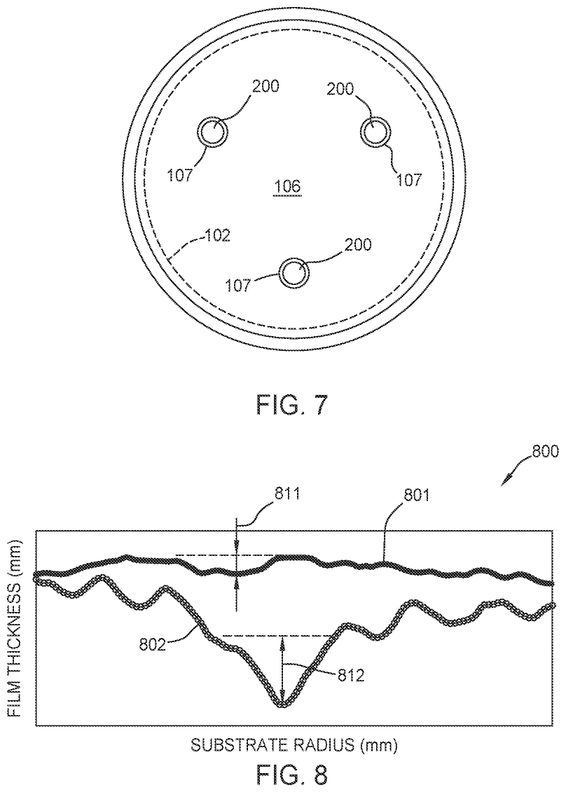

FIG. 7 is a schematic partial top view of the processing chamber 100 shown in FIG. 1 with the lift pin 200 shown in FIG. 2, according to one or more embodiments.

As shown in FIG. 1, the shaft sections 220 of the plurality of lift pins 200 are oriented parallel to each other. The plurality of lift pins 200 are spaced from each other long a geometric pattern. As shown in FIG. 7, the geometric pattern is a triangular pattern. Other geometric patterns are contemplated.

FIG. 8 is a graph 800 illustrating film thickness (in nm) versus substrate radius (in mm) for a region of a substrate aligned above a lift pin, according to one or more embodiments. The film thickness is a thickness of a film deposited on the substrate.

A first profile 801 shows the film thickness profile when the lift pin uses subject matter described herein. A second profile 802 shows the film thickness profile when the lift pin uses another configuration. By comparing the first profile 801 to the second profile 802, it is believed that the subject matter described herein facilitates increased film thickness (e.g., increased growth rates) for regions above lift pins (and other regions of the substrate, such as regions adjacent to the regions above the lift pins).

It is also believed that the subject matter described herein facilitates more uniform film thickness for regions above lift pins (and other regions of the substrate, such as regions adjacent to the regions above the lift pins). As an example, the first profile 801 includes a first thickness difference 811 and the second profile 802 includes a second thickness difference 812. The first thickness difference 811 can be one-half or less of the second thickness difference 812, such as one-third or less of the second thickness difference 812, for example one-fourth or less of the second thickness difference 812. It is believed that a reduction of 50% or higher, such as 70% or higher, in film thickness differences can be achieved to enhance film thickness uniformity. Additionally, it is believed that site-front-least-squares-range (SFQR) can be reduced by 45% or higher, such as 50% or higher, for example 65% or higher, for regions above lift pins (and other regions of the substrate, such as regions adjacent to the regions above the lift pins). The reduced film thicknesses facilitate enhanced nanotopography and surface flatness for processed substrates.

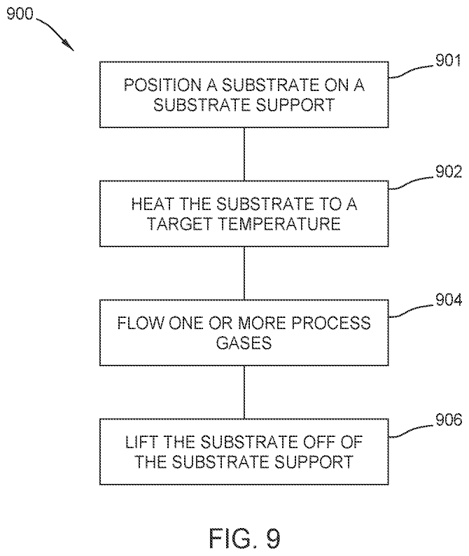

FIG. 9 is a schematic block diagram view of a method 900 of substrate processing for semiconductor manufacturing, according to one or more embodiments.

Operation 901 includes positioning a substrate on a substrate support in a processing volume of a processing chamber. In one or more embodiments, the positioning includes moving a substrate support and/or a plurality of lift pins relative to each other to land the substrate on the substrate support. One or more of the lift pins include any of the lift pins 200-600 described herein.

Operation 902 of the method 900 includes heating the substrate to a target temperature. In one or more embodiments, the target temperature is 600 degrees Celsius or higher, such as 1,000 degrees Celsius or higher.

Operation 904 includes flowing one or more process gases over the substrate to form one or more layers on the substrate.

Operation 906 includes lifting the substrate off of the substrate support. In one or more embodiments, the lifting includes moving a substrate support and/or a plurality of lift pins relative to each other to engage the substrate with the lift pins and lift the substrate.

Benefits of the present disclosure include reduced temperature differences (e.g., temperature gradients) across substrate supports, increased film thickness (e.g., increased growth rates), more uniform film deposition, enhanced nanotopography and surface flatness of process substrates, and reduced SFQR for substrates with film deposited thereon. Such benefits can be facilitated, for example, for regions above lift pins (and other regions of the substrate, such as regions adjacent to the regions above the lift pins). Such benefits can also be facilitated in a manner that reduces or eliminates chances of thermal shock of lift pins (and associated chances of defects, breakage, maintenance, and/or downtime), reduces or eliminates degradation of lift pins, and increases lifespans of lift pins. Benefits of the present disclosure also include reduced or eliminated chances of substrate defects (such as scratching and/or particle accumulation), higher processing temperatures, higher heating powers, enhanced device performance (including at reduced structure sizes), reduced processing times, reduced delays, reduced downtime, increase device yield, and increased throughput. For example, a heating temperature of 600 degrees Celsius or higher can be used, such as 1,000 degrees Celsius or higher.

It is contemplated that one or more aspects disclosed herein may be combined. As an example, one or more aspects, features, components, operations and/or properties of the various implementations of the processing chamber 100, the controller 120, the lift pin(s) 200, the lift pin(s) 300, the lift pin(s) 400, the lift pin(s) 500, the lift pin(s) 600, the graph 800, and/or the method 900 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing chamber applicable for use in semiconductor manufacturing, comprising:
a chamber body;
a window, the chamber body and the window at least partially defining a processing volume;
one or more heat sources configured to heat the processing volume;
a substrate support disposed in the processing volume; and
a plurality of lift pins disposed in the processing volume, the plurality of lift pins respectively comprising:
a shaft section having a first outer dimension,
a head section having a second outer dimension, and
an opening formed in the shaft section, the opening having a dimension that is:
a first ratio that is at least 0.3 of the first outer dimension of the shaft section, and
a second ratio that is at least 0.2 of the second outer dimension of the head section.

2. The processing chamber of claim 1, wherein the plurality of lift pins are disposed in openings formed in the substrate support.

3. The processing chamber of claim 1, wherein the shaft sections of the plurality of lift pins are oriented parallel to each other, and the plurality of lift pins are spaced from each other long a geometric pattern.

4. A lift pin applicable for semiconductor manufacturing, comprising:
a head section;
a shaft section extending relative to the head section; and
an opening formed in an end face of the shaft section and extending toward the head section.

5. The lift pin of claim 4, wherein the shaft section has an outer dimension and the opening has a dimension that is a ratio of the outer dimension of the shaft section, and the ratio is at least 0.3.

6. The lift pin of claim 4, wherein the head section has an outer dimension and the opening has a dimension that is a ratio of the outer dimension of the head section, and the ratio is at least 0.2.

7. The lift pin of claim 4, wherein the opening includes a recess extending along a longitudinal axis of the shaft section and defining a recessed inner surface at a distance from a support surface of the head section.

8. The lift pin of claim 7, wherein the distance is a ratio of a length of the lift pin, and the ratio is 0.05 or less.

9. The lift pin of claim 8, wherein the shaft section and the head section include glassy carbon.

10. The lift pin of claim 4, further comprising a second opening formed in a support surface of the head section and extending toward the shaft section.

11. The lift pin of claim 4, wherein the opening at least partially defines a wall of the shaft section, a thickness of the wall is a ratio of a dimension of the opening, and the ratio is 1.15 or less.

12. The lift pin of claim 4, wherein the opening at least partially defines a wall of the shaft section, and a thickness of the wall is within a range of 0.1 mm to 1.7 mm.

13. The lift pin of claim 4, wherein the opening is a through-hole extending from the end face of the shaft section and to a support surface of the head section.

14. A lift pin applicable for semiconductor manufacturing, comprising:
a head section comprising a first material;
a shaft section extending relative to the head section, the shaft section comprising a second material that has a different composition than the first material; and
an opening formed in the shaft section.

15. The lift pin of claim 14, wherein the second material has a lower thermal conductivity than the first material.

16. The lift pin of claim 14, wherein the second material includes glassy carbon, and the first material includes glassy carbon and a coating disposed on a support surface of the head section.

17. The lift pin of claim 16, wherein the coating includes silicon carbide (SiC) or quartz.

18. The lift pin of claim 14, wherein the shaft section has a first outer dimension and the opening has a dimension that is a first ratio of the first outer dimension of the shaft section, and the first ratio is at least 0.3.

19. The lift pin of claim 18, wherein the head section has a second outer dimension and the dimension of the opening is a second ratio of the second outer dimension of the head section, and the second ratio is at least 0.2.

20. The lift pin of claim 19, wherein the opening at least partially defines a wall of the shaft section, a thickness of the wall is a third ratio of the dimension of the opening, and the third ratio is 1.15 or less.
